(19) United States
(12) Patent Application Publication
(10) Pub. No.: US 2011/0075387 A1
(43) Pub. Date: Mar. 31, 2011

(54) Strain Measurement Chips For Printed Circuit Boards

(76) Inventors: Steven S. Homer, Tomball, TX (US); Mark S. Tracy, Tomball, TX (US); Kenneth D. Reddix, Spring, TX (US); Walter J. Rankins, Huntersville, NC (US)

(21) Appl. No.: 12/994,094

(22) PCT Filed: May 21, 2008
(86) PCT No.: PCT/US08/64292

§ 371 Date: Nov. 22, 2010

(51) Int. Cl. H05K 1/18; H05K 1/16; G01B 7/16

(52) U.S. Cl. 361/761; 174/260; 73/777

(57) ABSTRACT

A strain measurement chip including a body, a strain gauge provided within the body, and electrical contacts with which the strain measurement chip can be mounted to a circuit board, at least one of the electrical contacts being in electrical communication with the strain gauge to enable communication of strain data measured by the strain gauge to the circuit board.

### BACKGROUND

The printed circuit boards of some computing devices exhibit relatively high failure rates. For example, the motherboards of mobile computers, such as notebook or “laptop” computers, tend to fail more often than the motherboards of stationary computers. Such failures can be due to manufacturing processes. For example, damage may occur when a printed circuit board is twisted to fit within a computer housing. Failures can also occur during use. For example, damage may occur when a notebook computer is subjected to undue physical and/or thermal stresses.

Such failures can be reduced by evaluating the stresses that are typically imposed on the printed circuit boards. For example, if it is determined that a current manufacturing process imposes too much stress on a circuit board, alternative manufacturing processes can be used. The stress imposed upon a given circuit board can be determined by gluing strain gauges to the printed circuit board and collecting strain readings with wires that are attached to the strain gauges. Although such a solution can be effective, the process of gluing the strain gauges to the board is labor intensive and time consuming. In addition, because of the variability with which the stain gauges are glued to the boards in terms of location and orientation, such a solution may not provide consistent, and therefore dependable, results. Furthermore, such a solution can only be implemented before assembly of the computer in which the circuit board is to be installed has been completed.

### BRIEF DESCRIPTION OF THE DRAWINGS

The disclosed strain measurement chips can be better understood with reference to the following drawings. The components in the drawings are not necessarily to scale.

FIG. 1 is a cut-away top perspective view of a first embodiment of a strain measurement chip.

FIG. 2 is a top view of the strain measurement'chip of FIG. 1.

FIG. 3 is a bottom perspective view of a second embodiment of a strain measurement chip.

FIG. 4 is top perspective view of a printed circuit board having a strain measurement chip mounted thereon.

FIG. 5 is side view of the strain measurement chip of FIG. 1 shown attached to a printed circuit board.

FIG. 6 is a top view of the strain measurement chip and printed circuit board of FIG. 5, illustrating electrical connection of the chip to conductive traces of the circuit board.

FIG. 7 is a schematic top view of a further printed circuit board to which a strain measurement chip has been mounted.

FIG. 8 is side view of the strain measurement chip of FIG. 3 shown attached to a printed circuit board.

FIG. 9 is a perspective view of a computer that incorporates a strain measurement chip.

FIG. 10 is a block diagram of an embodiment of the computer of FIG. 9.

### DETAILED DESCRIPTION

As described above, it is desirable to measure the strain within a printed circuit board, such as a computer motherboard. Although strain data can be collected by gluing strain gauges to the circuit board, such a solution is disadvantageous for various reasons. As described in the following, such disadvantages can be reduced or avoided by mounting a strain measurement chip to the board. In some embodiments, the strain measurement chip comprises a semiconductor chip similar to an integrated circuit (IC) chip. Like conventional IC chips, the strain measurement chip comprises electrical contacts that can be directly connected, for instance soldered, to contact pads or traces provided on the board. Unlike an IC chip, however, the strain measurement chip comprises internal strain gauges that measure strains within the circuit board. Due to the connection of the leads or contacts to the traces of the circuit board, strain data can be communicated through the board, as opposed to through auxiliary wires.

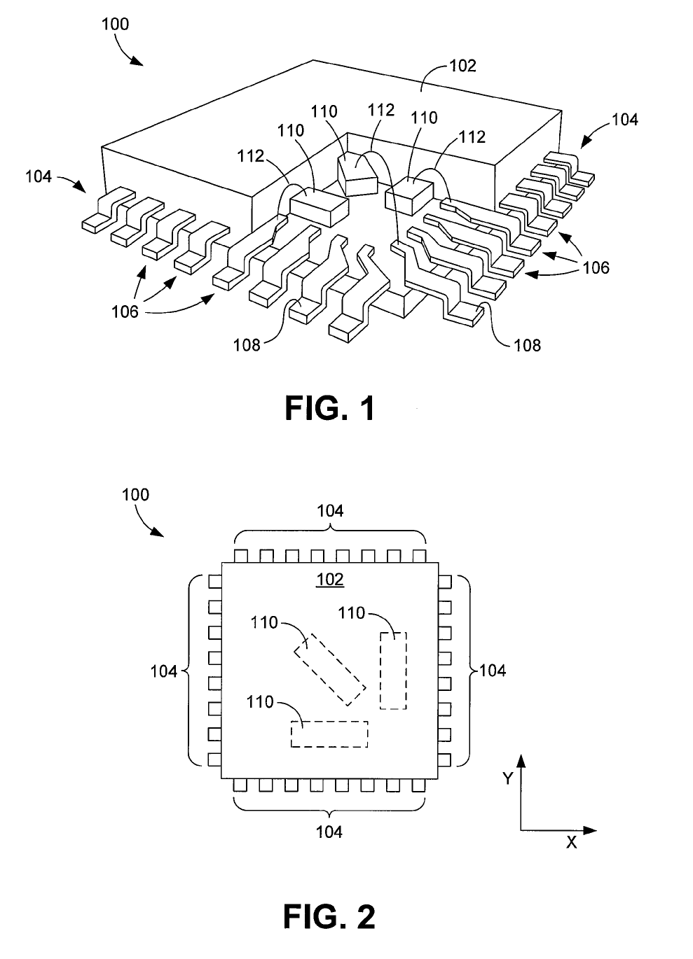

Referring now in more detail to the drawings, in which like numerals indicate corresponding parts throughout the several views, FIG. 1 illustrates a first example strain measurement chip 100 that can be mounted to a printed circuit board, such as a computer motherboard. As indicated in FIG. 1, the chip 100 has the general configuration of an IC chip. Therefore, the chip 100 comprises a substantially block-shaped body 102 having multiple sides from which outwardly (e.g., laterally) extend lead frames 104, each including multiple electrical leads 106. By way of example, the body 102 is formed of a semiconductor (e.g., silicon-based) and/or a polymer material, such as a silicon-based material and the leads 104 are made of an electrically-conductive material, such as a metal. In some embodiments, the chip 100 comprises four lead frames 104, one provided along each of the four sides of the chip (see FIG. 2). Each of the leads 106 comprises a foot 108 that can be attached to an element (e.g., contact pad) of a printed circuit board. Therefore, the leads 106 can be used to securely mount the chip 100 to the board. As described below, one or more of the leads 106 can also be used to communicate strain data measured by one or more internal strain gauges provided within the body 102. Although a particular number of leads 106 is shown in FIG. 1, it is to be understood that fewer or greater number of leads can be used depending, at least in part, on the strength of the bond desired between the chip 100 and its associated board.

As is further shown in FIG. 1, provided within the body 102 are one or more internal strain gauges 110. By way of example, the strain gauges 110 comprise piezo strain gauges. In the embodiment of FIG. 1, three such strain gauges 110 are provided, each being completely encompassed or encapsulated by the material of the chip body 102. As shown most clearly in the top view of FIG. 2, each strain gauge 110 has a different orientation within the chip 100 to enable measurement of strains in multiple different directions. In the embodiment of FIGS. 1 and 2, a first strain gauge 110 is aligned with an x direction, a second strain gauge 110 is aligned with a y direction, and a third strain gauge is aligned with a diagonal direction that forms an angle (e.g., 45°) with each of the x and y directions.

With further reference to FIG. 1, each strain gauge 110 is electrically coupled to at least one of the electrical leads 106. In the embodiment of FIG. 1, the strain gauges 110 couple to the leads 106 with supplemental conductors 112, such as internal wires. Alternatively, however, one or more of the leads 106 can be directly connected to each strain gauge 110.

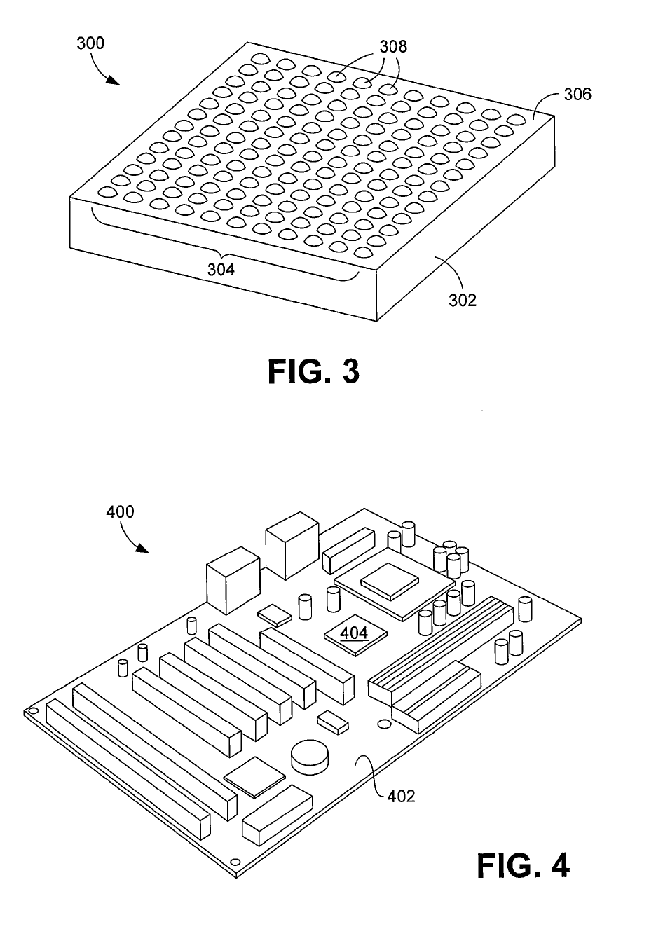

FIG. 3 illustrates a second example strain measurement chip 300. The strain measurement chip 300 is similar to the chip 100 and therefore comprises a body 302 that encapsulates strain gauges (not shown). The chip 300, however, does not comprise electrical leads that extend laterally from the body 302. Instead, the chip 300 comprises a ball grid array 304 formed on a bottom surface 306 of the body 302. The ball grid array 304 comprises a plurality rows and columns of solder balls or bumps 308. Like the electrical leads 106 of the chip 100, the solder bumps 306 can be used to securely mount the chip 300 to a printed circuit board. In addition, one or more of the solder bumps 306 can be used to communicate strain data measured by one or more of the internal strain gauges.

FIG. 4 illustrates an example printed circuit board 400, such as a motherboard intended for use in a computer. As shown in FIG. 4, the circuit board 400 includes various electrical components that are mounted to a top surface 402 of the circuit board. Such components can include processor chips, memory elements, electrical connectors, power sources, and the like. Also shown mounted to the surface 402 of the circuit board 400 is a strain measurement chip 404, which may have a configuration similar to that described above in relation to either FIG. 1 or FIG. 3. In the embodiment of FIG. 4, the strain measurement chip 404 to mounted to a central region of the circuit board 400. It is noted, however, that the chip 404 may be mounted in other locations. Furthermore, multiple such chips 404 may be mounted to the circuit board 400, if desired.

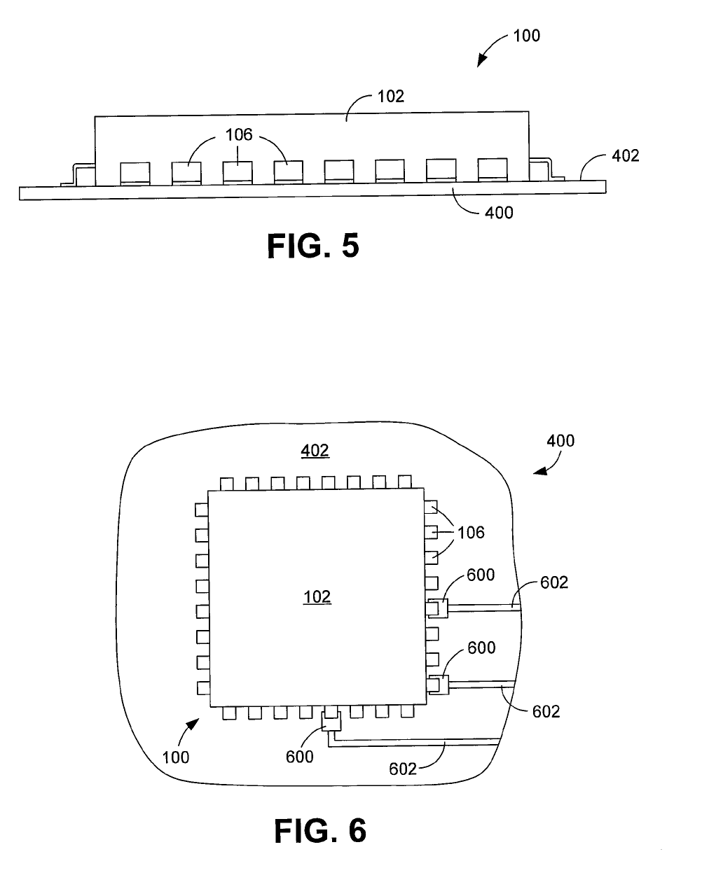

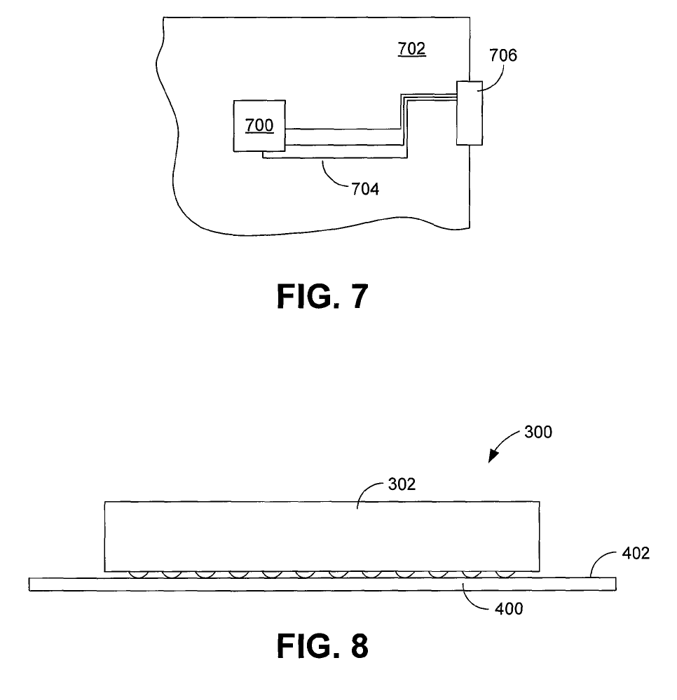

FIGS. 5 and 6 illustrate mounting of the strain measurement chip 100 to a portion of the printed circuit board 400 shown in FIG. 4. As indicated in FIG. 5, each of the electrical leads 106 is mounted to the surface 402 of the circuit board 400. For example, the feet 108 of the leads 106 are soldered to the surface 402. As indicated in FIG. 6, the leads 106 can be soldered to contact pads 600 formed on the surface 402 of the circuit board 400. As is further indicated in FIG. 6, one or more of the contact pads 600 can be electrically coupled to integral conductive traces 602 formed on or within the circuit board 400. Such traces 602 can be used to communicate strain data measured by the strain measurement chip 100 to a memory element on the circuit board 400, to another storage location within a computer in which the circuit board 400 is used (e.g., nonvolatile memory element), or to another device via a connector of the circuit board. The latter functionality is depicted in FIG. 7, in which a strain measurement chip 700 is mounted to a printed circuit board 702 and conductive traces 704 extend to an electrical connector 706 of the circuit board. By way of example, the connector 706 comprises a serial port or a universal serial bus (USB) connector. In such a case, strain data can be collected directly from the circuit board 702, for example by booting the circuit board independent of a computer in which it is to be installed. Testing can then be performed, for example during installation of the circuit board 702 into a housing of the computer.

FIG. 8 illustrates mounting of the strain measurement chip 300 to a portion of the printed circuit board 400. As with the chip 100, the chip 300 can be soldered to the circuit board 400. For example, the solder bumps 306 of the chip 300 can be soldered to contact pads (not shown) provided on the surface 402 of the circuit board 400. Again, one or more of those pads can be electrically coupled to conductive traces (not shown) formed on or within the circuit board 400 to enable communication of strain data using the circuit board.

Although the stain measurement chips 100, 300 have described as being soldered to a printed circuit board, it is noted that the chips can further be glued to the circuit board to keep them in place until soldering is performed and/or to provide additional strength to the bond formed between the chip and the circuit board.

Given that the above-described strain measurement chips are similar to conventional IC chips that mount to circuit boards, conventional automated manufacturing techniques can be used to mount the strain measurement chips. Such automation not only saves time and effort but also ensures consistency in the positioning and orientation of the strain gauges relative to the circuit board. Once a secure bond is achieved between the strain measurement chip and the circuit board, stresses imposed upon the circuit board will be transmitted to the strain measurement chip and its internal strain gauges. Strain data measured by the strain gauges can then be communicated directly to contact pads and conductive traces of the circuit board, thereby obviating the need for the separate wires that are necessary when individual strain gauges are simply glued to a circuit board. In addition, because the strain measurement chip is mounted and electrically coupled to the circuit board in similar manner to other surface mounted components, strain data can be collected after completion of assembly of a computer or other device in which the circuit board is used.

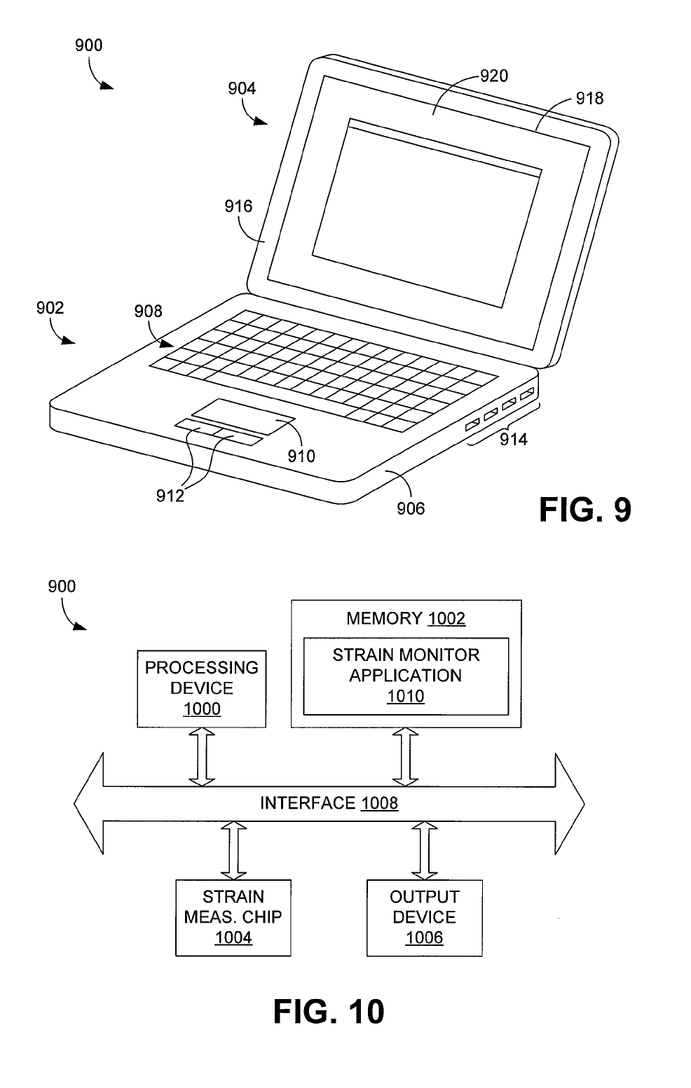

FIG. 9 illustrates an example application for a strain measurement chip of the type described herein. More particularly, FIG. 9 illustrates a notebook or “laptop” computer 900. As indicated in the figure, the computer 900 includes a base portion 902 and a display portion 904 that are attached to each other with a hinge mechanism (not shown). The base portion 902 includes an outer housing 906 that surrounds various internal components of the computer 900, including a motherboard that comprises a strain measurement chip that is mounted thereto. Also included in the base portion 902 are user input devices, including a keyboard 908, a mouse pad 910, and selection buttons 912, and various ports or connectors 914 that are accessible through the housing 906. The display portion 902 includes its own outer housing 916. Formed within the housing 916 is an opening 918 through which a display device 920 may be viewed.

As indicated in FIG. 10, the computer 900 includes a processing device 1000, memory 1002, the strain measurement chip 1004, and an output device 1006, each of which is connected to an interface 1008, such as an internal bus. Stored in memory 1002 is a strain monitor application 1010 that collects strain data from the strain measurement chip 1004. With such an application 1010, strain within the motherboard can be stored over time. In addition or exception, strain data can be output from the computer 900 via the output device 1006, which can comprise a serial port, USB connector, Firewire connector, Ethernet connector, or other communication connector or device.

Although a notebook computer has been identified as a possible application for the strain measurement chip, it is to be appreciated that the strain measurement chip can be used with substantially any circuit board, whether it is present with a notebook computer or another device or machine. For example, the strain measurement chip can be provided on the circuit boards of any of desktop computers, tablet computers, personal digital assistants, mobile phones, portable game units, vehicles, appliances, and so forth.

1. A strain measurement chip comprising:
a body;
a strain gauge provided within the body; and
electrical contacts with which the strain measurement chip can be mounted to a circuit board, at least one of the electrical contacts being in electrical communication with the strain gauge to enable communication of stain data measured by the strain gauge to the circuit board.

2. The strain measurement chip of claim 1, wherein the body is composed of a semiconductor material.

3. The strain measurement chip of claim 1, wherein the body is composed of a polymer material.

4. The strain measurement chip of claim 1, wherein multiple strain gauges are provided within the body.

5. The strain measurement chip of claim 4, wherein the multiple strain gauges are oriented in different directions.

6. The strain measurement chip of claim 4, wherein a first strain gauge is aligned in a first direction and a second strain gauge is aligned in a second direction perpendicular to the first direction.

7. The strain measurement chip of claim 6, wherein a third strain gauge is aligned in a diagonal direction that forms an angle with the first and second directions.

8. The strain measurement chip of claim 1, wherein the electrical contacts comprise electrical leads that extend laterally outward from the body.

9. The strain measurement chip of claim 8, wherein the electrical leads comprise feet that are configured to be soldered to contact pads of the circuit board.

10. The strain measurement chip of claim 1, wherein the electrical contacts comprise solder bumps provided on a bottom surface of the body, the solder bumps being configured to be soldered to contact pads of the circuit board.

11. A strain measurement chip comprising:
a block-shaped body;
multiple internal strain gauges encapsulated within the body, each strain gauge being aligned with a different direction; and
electrical contacts configured to be soldered to contact pads provided on a surface of a circuit board, at least some of the electrical contacts being in electrical communication with the internal strain gauges to enable communication of stain data measured by the internal strain gauges to the circuit board.

12. The strain measurement chip of claim 11, wherein the body is composed of a semiconductor material.

13. The strain measurement chip of claim 11, wherein the body is composed of a polymer material.

14. The strain measurement chip of claim 11, wherein a first strain gauge is aligned in a first direction, a second strain gauge is aligned in a second direction perpendicular to the first direction, and a third strain gauge is aligned in a diagonal direction that forms an angle with the first and second directions.

15. The strain measurement chip of claim 11, wherein the electrical contacts comprise electrical leads that extend laterally outward from sides of the body and that comprise feet that are configured to be soldered to the contact pads of the circuit board.

16. The strain measurement chip of claim 11, wherein the electrical contacts comprise solder bumps of a ball grid array formed on a bottom surface of the body, the solder bumps being configured to be soldered to the contact pads of the circuit board.

17. A circuit board comprising:
a top surface;
contact pads formed on the top surface; and
a strain measurement chip mounted to the top surface, the strain measurement chip comprising a body, a strain gauge provided within the body, and electrical contacts that are soldered to the contact pads, wherein at least one of the electrical contacts is in electrical communication with the strain gauge to enable communication of stain data measured by the strain gauge to the circuit board.

18. The circuit board of claim 17, wherein the strain measurement chip comprises multiple strain gauges oriented in different directions.

19. The circuit board of claim 17, wherein a first strain gauge is aligned in a first direction, a second strain gauge is aligned in a second direction perpendicular to the first direction, and a third strain gauge is aligned in a diagonal direction that forms an angle with the first and second directions.

20. The circuit board of claim 17, wherein the electrical contacts of the strain measurement chip comprise electrical leads that extend laterally outward from the body of the strain measurement chip.

21. The circuit board of claim 17, wherein the electrical contacts of the strain measurement chip comprise solder bumps provided on a bottom surface of the body of the strain measurement chip.

22. A computer comprising:
a processor;
memory;
a circuit board including a top surface having contact pads formed thereon; and
a strain measurement chip mounted to the top surface of the circuit board, the strain measurement chip comprising a body, a strain gauge provided within the body, and electrical contacts that are soldered to the contact pads, wherein at least one of the electrical contacts is in electrical communication with the strain gauge to enable communication of stain data measured by the strain gauge to the circuit board.

23. The computer of claim 22, wherein the strain measurement chip comprises multiple strain gauges oriented in different directions.

24. The computer of claim 22, wherein the circuit board is a motherboard and wherein the processor and memory are mounted to the circuit board.

25. The computer of claim 22, wherein computer is a notebook computer.
